(19) United States
(12) Patent Application Publication
(10) Pub. No.: US 2004/0259344 A1
(43) Pub. Date: Dec. 23, 2004

(54) Method for forming a metal layer method for manufacturing a semiconductor device using the same

(76) Inventors: Dong-Kyun Park, Gyeonggi-do (KR); Ju-Cheol Shin, Seoul (KR); Hyeon-Deok Lee, Seoul (KR); In-Sun Park, Kyeonggi-do (KR); Hyun-Seok Lim, Gyeonggi-do (KR)

Correspondence Address: MARGER JOHNSON & McCOLLOM, P.C., 1030 S.W. Morrison Street, Portland, OR, 97205, US

(21) Appl. No.: 10/830,896

(22) Filed: Apr. 22, 2004

(30) Foreign Application Priority Data
Apr. 24, 2003 (KR) 2003-26023

(51) Int. Cl. H01L 21/28; H01L 21/3205; H01L 21/20; H01L 21/4763

(52) U.S. Cl. 438/605; 438/584; 438/637; 438/631

(57) ABSTRACT

A preliminary metal layer having a first thickness is formed on a substrate. A surface of the preliminary metal layer having uneven portions is etched to remove the uneven portions and to form a metal layer having an improved surface morphology. Therefore, shorts caused by the surface morphology of a metal layer occur less frequently and the semiconductor fabricating yield improves.

### CROSS REFERENCE TO RELATED APPLICATION

This application claims priority under 35 USC § 119 to Korean Patent Application No. 2003-26023, filed on Apr. 24, 2003, the contents of which are herein incorporated by reference in their entirety for all purposes.

### BACKGROUND OF THE INVENTION

1. Field of the Invention

The present invention relates to a method for forming a metal layer and a method for manufacturing a semiconductor device using the same. More particularly, the present invention relates to a method for forming a metal layer having improved surface morphology, and a method for manufacturing a semiconductor device using the same.

2. Description of the Related Art

As an information-oriented society has rapidly developed, highly integrated semiconductor devices are required to rapidly process massive amounts of information. Accordingly, the physical width of a wiring and the interval between adjacent wirings in semiconductor devices are increasingly diminished. As a result, the resistance of a conductive pattern or a conductive line formed as the wiring remarkably increases.

Typically, the conductive pattern, for example, a gate electrode or a bit line, is formed from polysilicon or metal silicide having a high resistance. However, a method for forming a conductive pattern has been recently researched and developed, which uses a metal material, for example, tungsten, having a resistance lower than that of polysilicon or metal silicide and being stably maintained during the formation of the conductive pattern.

FIGS. 1A to 1C are cross sectional views illustrating a conventional method for forming a tungsten pattern of a semiconductor device.

Referring to FIG. A, a tungsten layer 12 is formed on a semiconductor substrate 10. The tungsten layer 12 may be formed through a chemical vapor deposition (CVD) process using a tungsten fluoride (WF₆) source, a silane (SiH₄) source, and a hydrogen (H₂) source. Here, the tungsten layer 12 exhibits poor surface morphology characteristics.

Referring to FIG. 1B, a hard mask pattern 14 including nitride is formed on the tungsten layer 12. The tungsten layer 12 is etched using the hard mask pattern 14 as an etching mask to form a tungsten pattern 12a. Since the tungsten layer 12 has bad surface morphology characteristics, minute uneven portions are formed on an upper face and a side face of the tungsten pattern 12a.

Referring to FIG. 1C, spacers 16 are formed on the side faces of the tungsten pattern 12a. An insulating interlayer 19 is formed on the resultant structure. A self-aligned contact 20 is formed between the tungsten pattern 12a.

The minute uneven portions grow in side directions due to thermal budget (see area A). Accordingly, the tungsten pattern 12a and the self-aligned contact 20 may become electrically interconnected. As the interval between the tungsten patterns 12a has been smaller that is below about 100 nm, the interconnection between the tungsten pattern 12a and the self-aligned contact 20 often occurs. To reduce the interconnection, the tungsten layer 12 may have improved surface morphology.

To improve the surface morphology of the tungsten layer, conditions for deposition of tungsten may be optimized. There is, however, a limit to the improvements that can be achieved using the conventional method.

Embodiments of the invention address these and other disadvantages of the conventional art.

### SUMMARY OF THE INVENTION

Some embodiments of the invention provide a method for forming a metal layer capable of improving surface morphology of a metal layer. Other embodiments of the invention provide a method for manufacturing a semiconductor device that includes a metal wiring. Still other embodiments of the invention provide a method for manufacturing a semiconductor device that includes a bit line having improved surface morphology.

In accordance with a method for forming a metal layer according to one aspect of the present invention, a reserve metal layer having a first thickness is formed on a substrate. A surface of the reserve metal layer having uneven portions is etched for removing the uneven portions to form a metal layer.

In accordance with a method for manufacturing a semiconductor device according to one aspect of the present invention, a conductive pattern is formed on a substrate. An insulating interlayer is formed on the substrate and the conductive pattern. The insulating interlayer is etched to form a contact hole for exposing an upper surface of the conductive pattern. A reserve metal layer having a first thickness is formed on the insulating interlayer to fill the contact hole. A surface of the reserve metal layer having uneven portions is etched for removing the uneven portions to form a metal layer having a second thickness. The metal layer is etched to form a metal layer pattern.

In accordance with a method for manufacturing a semiconductor device according to another aspect of the present invention, MOS transistors having source/drain regions are formed on a substrate having a cell region and a peripheral region. A first insulating layer is formed on the MOS transistors. Contact pads are formed through the first insulating layer to make contact with the source/drain regions disposed in the cell region. A second insulating layer is formed on the contact pads. The second insulating layer is etched to form a contact hole exposing a bit line contact region. A reserve metal layer having a first thickness is formed on the second insulating layer to fill the contact hole. A surface of the reserve metal layer having uneven portions is etched for removing the uneven portions to form a metal layer having a second thickness. The metal layer is etched to form a bit line.

According to the present invention, the reserve metal layer has improved surface morphology due to a surface treatment. Therefore, when the metal layer is patterned, short between the metal layer and a conductive contact caused from the surface morphology may not occur.

### BRIEF DESCRIPTION OF THE DRAWINGS

The above and other objects and advantages of the invention will become readily apparent by reference to the following detailed description when considered in conjunction with the accompanying drawings.

FIGS. 1A to 1C are cross sectional views illustrating a conventional method for forming a tungsten pattern.

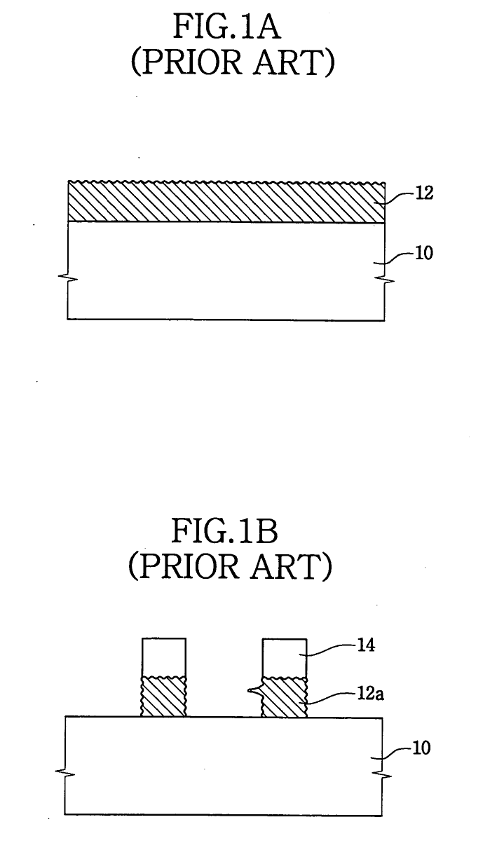

FIGS. 2A to 2C are cross sectional views illustrating a method for forming a metal pattern on a substrate according to some embodiments of the invention.

FIG. 3A is a scanning electron microscope picture showing a surface of a tungsten layer produced by a first embodiment of the invention FIG. 3B is a scanning electron microscope picture showing a cross section of the tungsten layer of FIG. 3A.

FIG. 4A is a scanning electron microscope picture showing a surface of a tungsten layer produced by a second embodiment of the invention.

FIG. 4B is a scanning electron microscope picture showing a cross section of the tungsten layer of FIG. 4A.

FIG. 5A is a scanning electron microscope picture showing a surface of a tungsten layer produced by a first comparative example.

FIG. 5B is a scanning electron microscope picture showing a cross section of the tungsten layer of FIG. 5A.

FIG. 6A is a scanning electron microscope picture showing a surface of a tungsten layer produced by a sixth comparative example.

FIG. 6B is a scanning electron microscope picture showing a cross section of the tungsten layer of FIG. 6A.

FIG. 7A is a scanning electron microscope picture showing a surface of a titanium nitride layer produced by a third embodiment of the invention.

FIG. 7B is a scanning electron microscope picture showing a cross section of the titanium nitride layer of FIG. 7A.

FIG. 8 is a plan view illustrating a DRAM device according to some embodiments of the invention;

FIGS. 9A to 9E are cross sectional views taken in a direction substantially parallel to a bit line of the DRAM device of FIG. 8.

FIGS. 9F and 9G are cross sectional views taken in a direction substantially parallel to a gate line of the DRAM device of FIG. 8.

### DETAILED DESCRIPTION OF THE INVENTION

Hereinafter, a method for forming a metal layer and a method for manufacturing a semiconductor device using the same according to embodiments of the invention is illustrated in detail.

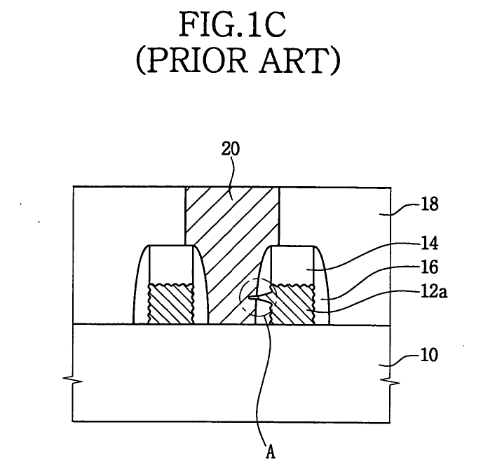

FIGS. 2A to 2C are cross sectional views illustrating a method for forming a metal pattern on a substrate according to some embodiments of the invention.

Referring to FIG. 2A, a preliminary metal layer 102 is formed on a semiconductor substrate 100 through a chemical vapor deposition (CVD) process. A thickness of the preliminary metal layer 102 is about 50 Å to about 500 Å thicker than that of a metal layer that is subsequently formed on the substrate 100.

The preliminary metal layer 102 may include a tungsten layer, a titanium nitride layer, a tantalum nitride layer, or a multi-layer thereof. For example, the tungsten layer may be formed using tungsten fluoride (WF₆), silane (SiH₄) and hydrogen (H₂) as a source. A metal barrier layer (not shown) may also be formed prior to forming the preliminary metal layer 102. Minute uneven portions are formed on an upper face of the preliminary metal layer 102 through the CVD process.

Referring to FIG. 2B, a surface treatment is performed on the upper face of the preliminary metal layer 102 to improve the surface morphology of the preliminary metal layer 102. The surface treatment may include an etching process. The surface treatment is performed at an etching rate of below about 800 Å/min.

In particular, the surface treatment is performed on the preliminary metal layer 102 by introducing a gas including chlorine so that a metal layer 104 is formed on the substrate 100. That is, the preliminary metal layer 102 is changed into the metal layer 104 by the surface treatment. The surface treatment may be performed in a vacuum chamber. The surface treatment may be performed at a power of about 200 watts to about 1,000 watts under a pressure of below about 200 mTorr. A magnetic force of about 10 gauss to about 50 gauss may be applied to the vacuum chamber.

The upper face of the preliminary metal layer 102 reacts with chlorine to form a non-volatile metal chloride, for example, tungsten chloride (WCl). The non-volatile metal chloride is removed at a rate of below about 700 Å/min. Since projections from the upper face of the preliminary metal layer 102 are etched in advance, the uneven portions of the preliminary metal layer 102 are reduced. Accordingly, a metal layer 104 having improved surface morphology is formed through the surface treatment.

Meanwhile, the surface treatment is preferably performed by removing the upper face of the preliminary metal layer 102 by a minimum thickness to improve the surface morphology of the preliminary metal layer 102. Preferably, about 50 Å to about 500 Å of the upper face of the preliminary metal layer 102 is removed. Additionally, the chlorine gas may be introduced into the vacuum chamber at a flow rate of about 30 sccm to about 150 sccm for about 5 seconds to about 60 seconds.

Alternatively, the preliminary metal layer 102 and the metal layer 104 may be formed through an in-situ process in a single chamber. Alternatively, the preliminary metal layer 102 and the metal layer 104 may also be formed through an ex-situ process.

The chlorine gas is provided not to etch the preliminary metal layer 102 but to improve the surface morphology of the preliminary metal layer 102. Thus, rapid etching of the preliminary metal layer 102 is not required. When the preliminary metal layer 102 is rapidly etched, too much material is removed from the preliminary metal layer 102. As a result, the preliminary metal layer 102 is initially formed thicker to compensate for the excessively removed material. Furthermore, the metal layer 104 having uniform thickness may hardly be formed on the substrate 100 after the surface treatment.

In a conventional method for forming a contact plug disclosed in Japan Patent Laid Open Publication No. 09-022811, a metal layer having a high melting point is formed in a contact hole. A gas containing oxygen chloride is introduced onto the metal layer. However, the gas containing oxygen chloride rapidly removes the metal layer formed on an upper face of the contact hole to form a contact plug. Thus, the gas containing oxygen chloride may be inappropriate for a gas used to treat a surface of a metal layer while removing the surface of the metal layer by a minimum thickness.

Referring to FIG. 2C, a hard mask including silicon nitride is formed on the metal layer 104. The hard mask is etched through a photolithography process to form a hard mask pattern 106. Intervals between the hard mask patterns 106 are below about 100 nm. The metal layer 104 is etched using the hard mask pattern 106 as an etching mask to form a metal pattern 104a.

The metal layer 104 has improved surface morphology relative to the preliminary metal layer 102. When a self-aligned contact is formed between the metal patterns 104a, shorts between the metal pattern 104a and the self-aligned contact are prevented.

Hereinafter, specific exemplary embodiments of a method for forming a metal layer having improved surface morphology on a substrate are illustrated in detail.

According to a first embodiment of the invention, a preliminary tungsten layer having a thickness of about 500 Å was formed on a silicon substrate. The silicon substrate was disposed in a chamber. The chamber was set under pressure of about 150 mTorr. A power of about 500 watts was applied to the chamber. A magnetic force of about 30 gauss was also applied to the chamber. A chloride gas was introduced into the chamber at a flow rate of about 70 sccm. The surface treatment was performed on the preliminary tungsten layer for ten seconds to form a tungsten layer. About 100 Å of the preliminary tungsten layer was removed. That is, the etching rate of the preliminary tungsten layer was about 600 Å/min. The tungsten layer had a thickness of about 400 Å.

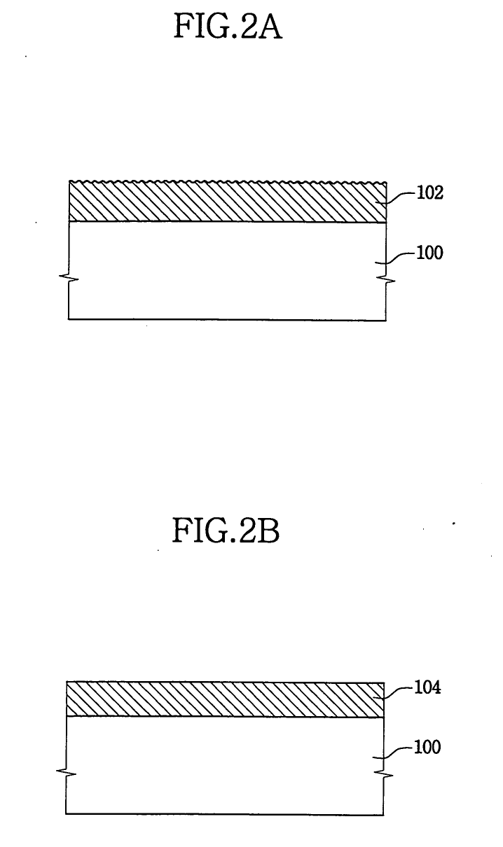

FIG. 3A is a scanning electron microscope picture showing a surface of a tungsten layer produced by the first embodiment of the invention. FIG. 3B is a scanning electron microscope picture showing a cross section of the tungsten layer of FIG. 3A.

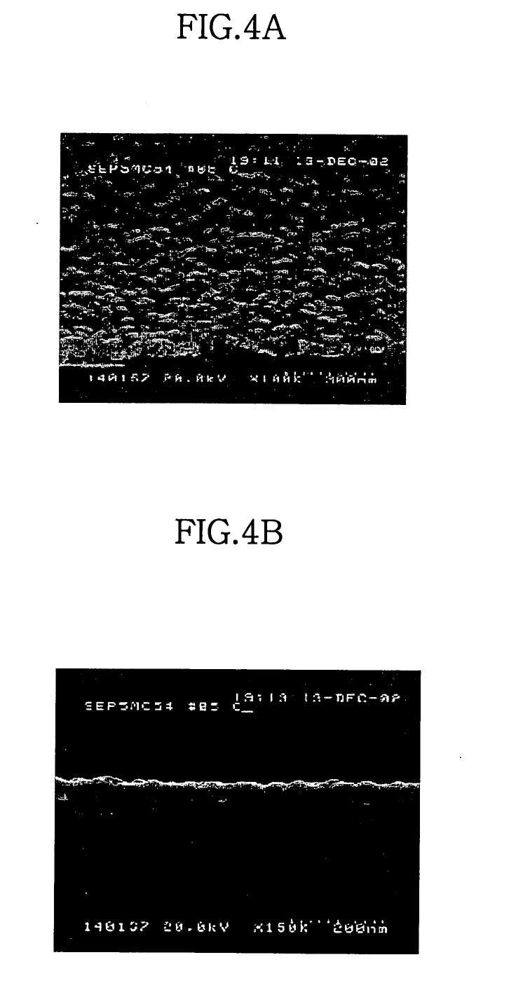

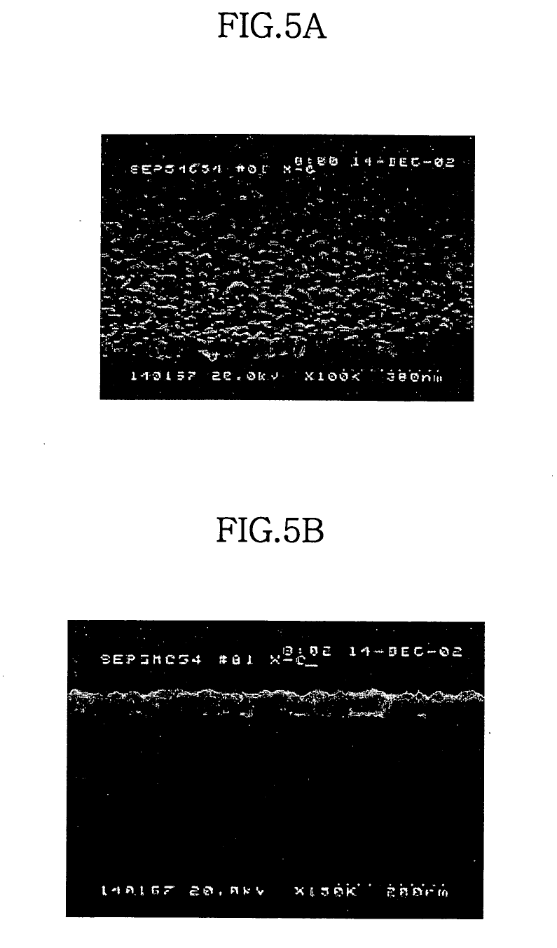

Referring to FIGS. 3A and 3B, it should be noted that the surface and the cross section of the tungsten layer produced by the first embodiment had improved surface morphology compared to that of the tungsten layer not processed by the surface treatment according to a first comparative example (see FIGS. 5A and 5B).

According to a second embodiment of the invention, a preliminary tungsten layer having a thickness of about 600 Å was formed on a silicon substrate. The surface treatment was performed on the preliminary tungsten layer for twenty seconds under conditions substantially identical to those of the first embodiment to form a tungsten layer. The preliminary tungsten layer was removed by a thickness of about 200 Å. The tungsten layer had a thickness of about 400 Å.

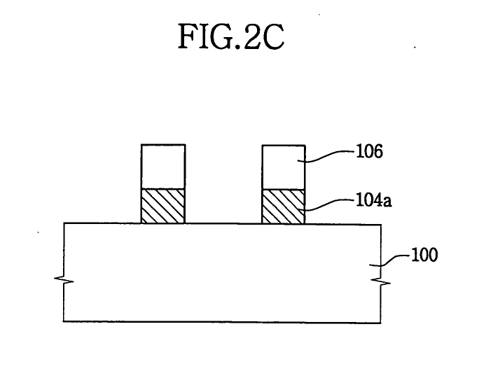

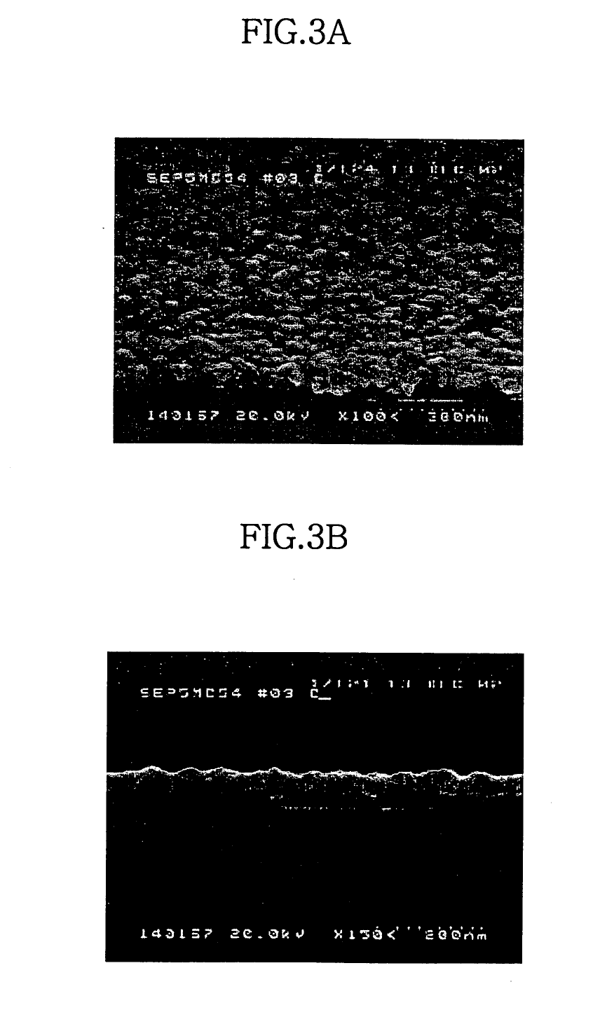

FIG. 4A is a scanning electron microscope picture showing a surface of a tungsten layer produced by the second embodiment of the invention. FIG. 4B is a scanning electron microscope picture showing a cross section of the tungsten layer in FIG. 4A.

Referring to FIGS. 4A and 4B, it should be noted that the surface and the cross section of the tungsten layer produced by the second embodiment had improved surface morphology compared to that of the tungsten layer produced according to a first comparative example (see FIGS. 5A and 5B).

According to a first comparative example, a preliminary tungsten layer having a thickness of about 400 Å was formed on a silicon substrate. A surface treatment as taught by embodiments of the invention was not performed on the preliminary tungsten layer.

FIG. 5A is a scanning electron microscope picture showing a surface of a tungsten layer produced according to the first comparative example. FIG. 5B is a scanning electron microscope picture showing a cross section of the tungsten layer of FIG. 5A.

The respective characteristics of the tungsten layers according to the first and second embodiments and the first comparative example are shown in Table 1 below.

TABLE 1

| | Reflective | Surface roughness | Specific |
|---|---|---|---|
| | index(%) | (root mean square of Å) | resistance(Wcm) |
| first | 77.1 | 45.7 | 15.4 |
| embodiment | | | |
| second | 77.5 | 48.2 | 14.7 |
| embodiment | | | |
| first | 68.9 | 52.2 | 16.9 |
| comparative | | | |
| example | | | |

Table 1 indicates that the respective reflective indices of the tungsten layers produced by the first and second embodiments were augmented by about 6% relative to that of the tungsten layer produced by the first comparative example. Table 1 also illustrates that the respective surface roughness of the tungsten layer according to the first and second embodiments were also lowered by a thickness of about 4 Å to about 7 Å relative to that of the tungsten layer of the first comparative example.

In accordance with the results of above comparison, it should be noted that the tungsten layers produced by the first and second embodiments had surface morphologies that were improved by about 13% relative to the tungsten layer that produced by the first comparative example. It should also be noted that the tungsten layers produced by the first and second embodiments had specific resistances that were improved by about 8% relative to the tungsten layer of the first comparative example.

In a second comparative example, a tungsten layer having a thickness of about 797 Å was formed on a silicon substrate.

In a third comparative example, a tungsten layer having a thickness of about 797 Å was formed on a silicon substrate. The silicon substrate was disposed in a chamber. The chamber was set under pressure of about 4 mTorr. A power of about 500 watts was applied to the chamber. A chloride gas at a flow rate of about 70 sccm, a nitrogen fluorine gas at a flow rate of about 20 sccm and a nitrogen gas at a flow rate of about 20 sccm were introduced into the chamber. The surface treatment was performed on the preliminary tungsten layer for ten seconds to form a tungsten layer. The preliminary tungsten layer was removed by a thickness of about 148 Å. That is, the etching rate of the preliminary tungsten layer was about 888 Å/min. The tungsten layer had a thickness of about 649 Å.

The etching rate of the tungsten layer according to the third comparative example was faster than that of the tungsten layers according to the first and second embodiments of the invention. As a result, a thicker tungsten layer—might be formed before the surface treatment. It also may be—difficult to uniformly maintain the thickness of the tungsten layer after the surface treatment.

The respective characteristics of the tungsten layer of the second comparative example and the tungsten layer of the third comparative example were compared. The specific resistance of the tungsten layer according to the second comparative example was about 16.8 Wm, and that of the tungsten layer according to the third comparative example was about 16.4 Wm. The specific resistance of the tungsten layer was little reduced through the surface treatment according to the third comparative example.

Additionally, the reflective index of the tungsten layer according to the second comparative example was about 74%, and that of the tungsten layer according to the third comparative example was about 80%. The tungsten layer processed by the surface treatment according to the third comparative example had specific resistances improved by about 8% relative to the tungsten layer not processed by the surface treatment according to the second comparative example.

In a fourth comparative example, a tungsten layer having a thickness of about 804 Å was formed on a silicon substrate.

In a fifth comparative example, a tungsten layer having a thickness of about 804 Å was formed on a silicon substrate. The silicon substrate was disposed in a chamber. The chamber was set under pressure of about 4 mTorr. A power of about 500 watts was applied to the chamber. A nitrogen fluorine gas at a flow rate of about 20 sccm and a nitrogen gas at a flow rate of about 20 sccm were introduced into the chamber. The surface treatment was performed on the preliminary tungsten layer for ten seconds to form a tungsten layer. The preliminary tungsten layer was removed by a thickness of about 99 Å. Thus, the etching rate of the preliminary tungsten layer was about 594 Å/min. The tungsten layer had a thickness of about 705 Å.

The respective characteristics of the tungsten layer of the fourth and fifth comparative examples were also compared. The specific resistance of the tungsten layer according to —the fourth comparative example was about 16.6 Wm, and that of the tungsten layer according to the fifth comparative example was about 16.4 Wm. The specific resistance of the tungsten layer was little reduced through the surface treatment according to the fifth comparative example.

Additionally, the reflective index of the tungsten layer according to the fourth comparative example was about 71%, and that of the tungsten layer according to the fifth comparative example was about 77%. The tungsten layer processed by the surface treatment according to the fifth comparative example had specific resistances improved by about 8% relative to the tungsten layer not processed by the surface treatment according to the second comparative example.

According to a sixth comparative example, a titanium nitride layer was formed on a silicon substrate through a metal-organic chemical vapor deposition (MOCVD) process.

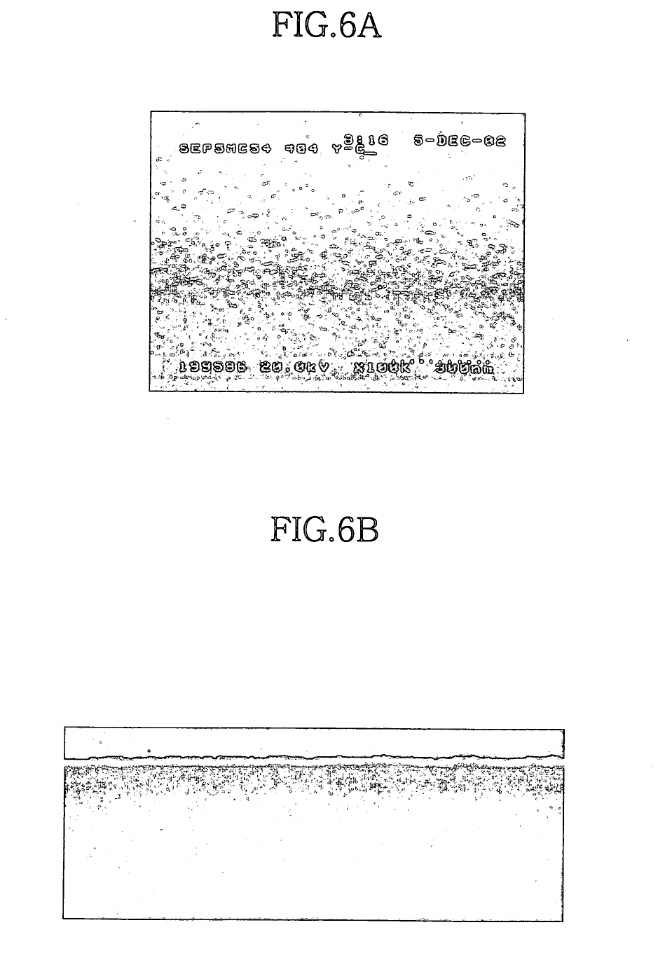

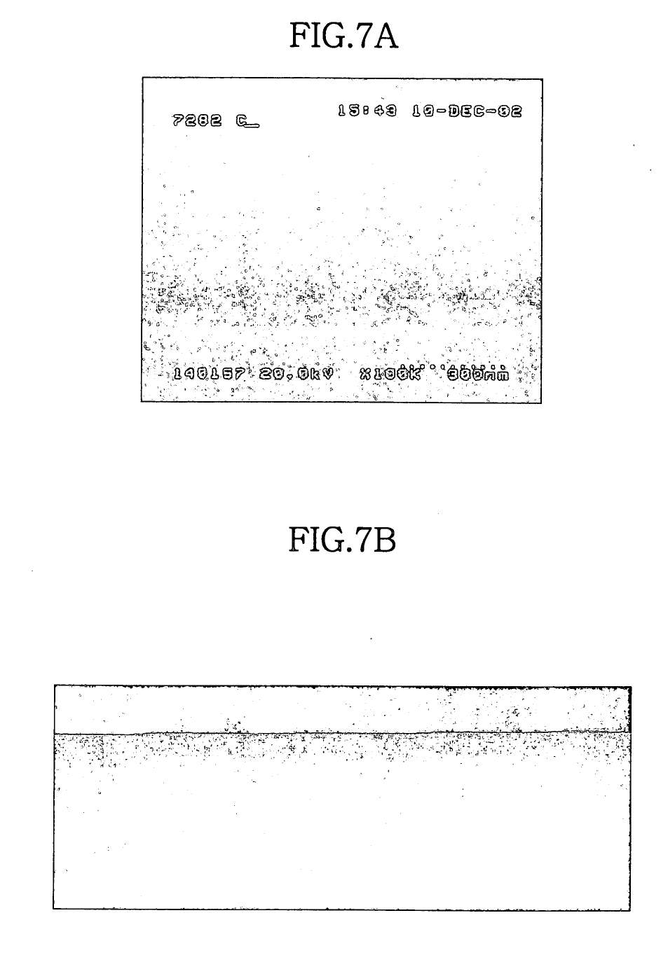

FIG. 6A is a scanning electron microscope picture showing a surface of a tungsten layer according to the sixth comparative example. FIG. 6B is a scanning electron microscope picture showing a cross section of the tungsten layer in FIG. 6A.

According to a third embodiment of the invention, a titanium nitride layer was formed on a silicon substrate through a metal-organic chemical vapor deposition (MOCVD) process. The silicon substrate was disposed in a chamber. The chamber was set under pressure of about 150 mTorr. A power of about 500 watts was applied to the chamber. A magnetic force of about 30 gauss was also applied to the chamber. A chloride gas was introduced into the chamber at a flow rate of about 70 sccm. The surface treatment was performed on the titanium nitride layer for ten seconds.

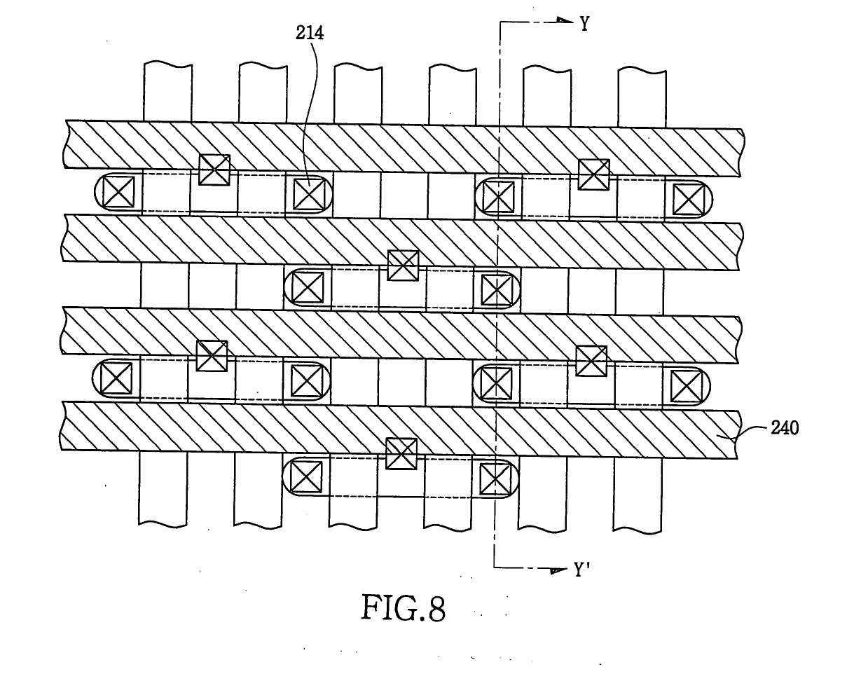

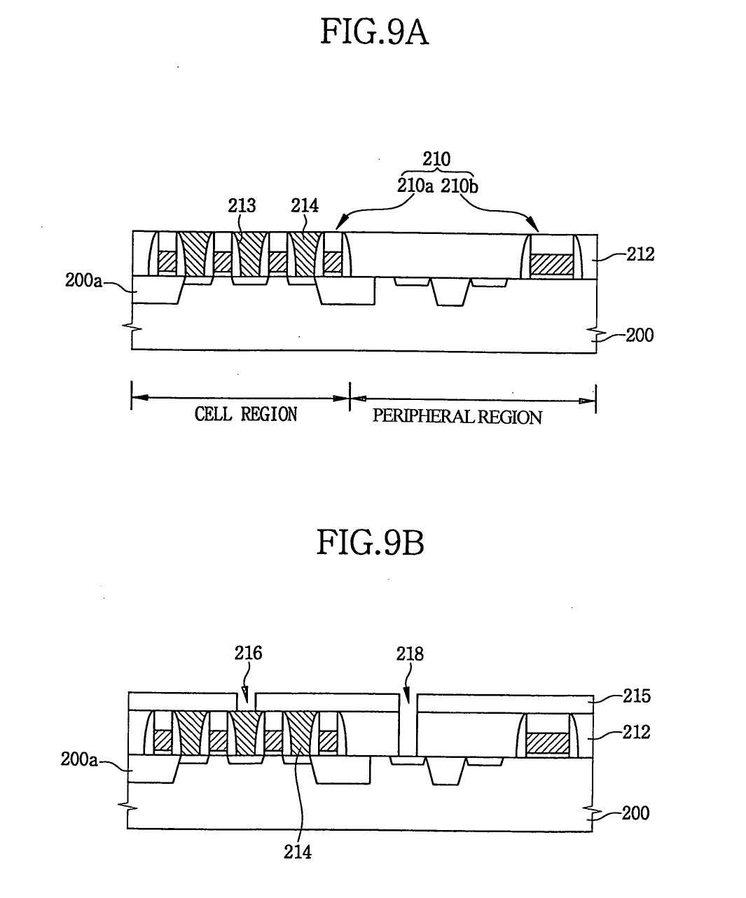

FIG. 7A is a scanning electron microscope picture showing a surface of a titanium nitride layer according to the third embodiment of the invention. FIG. 7B is a scanning electron microscope picture showing a cross section of the titanium nitride layer of FIG. 7A.

Referring to FIGS. 7A and 7B, it should be noted that the surface and the cross section of the tungsten layer processed by the surface treatment had improved surface morphology compared to that of the tungsten layer produced by the sixth comparative example (see FIGS. 6A and 6B).

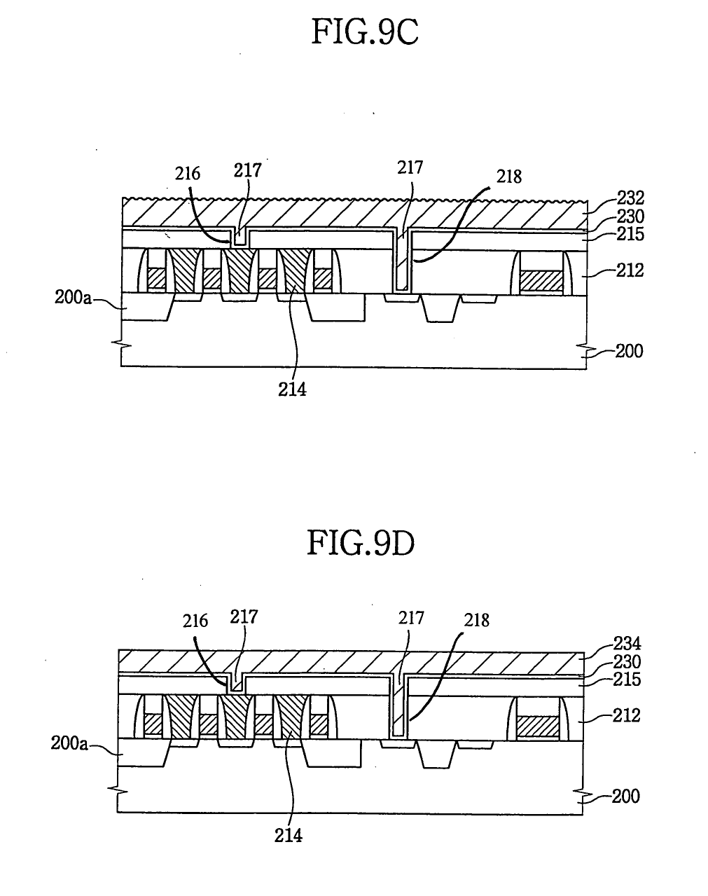

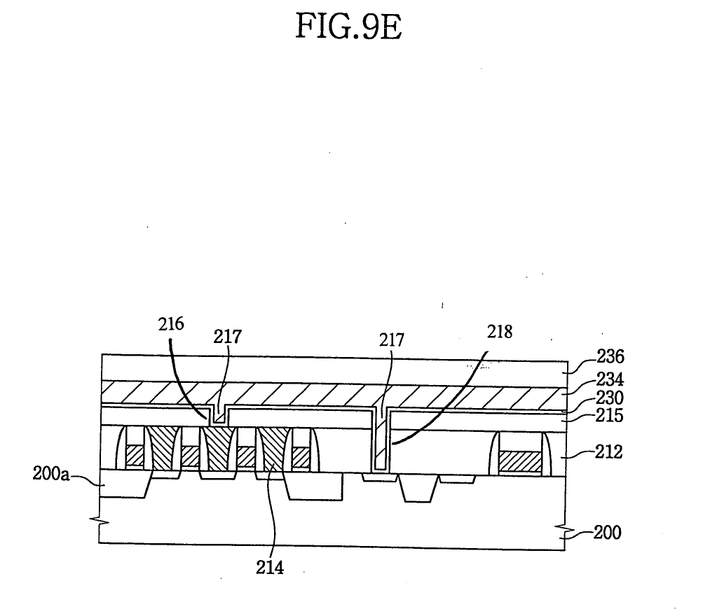

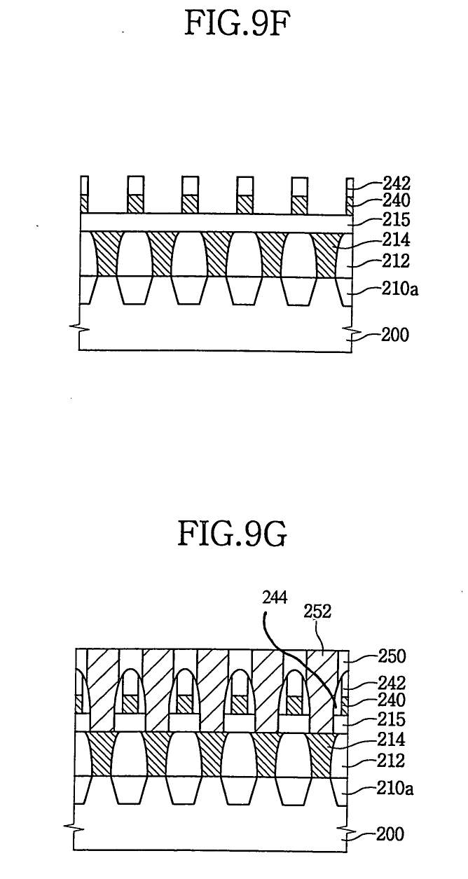

FIG. 8 is a plan view illustrating a DRAM device according to some embodiments of the—invention. FIGS. 9A to 9E are cross sectional views taken in a direction substantially parallel to a bit line of the DRAM device in FIG. 8. FIGS. 9F and 9G are cross sectional views taken in a direction substantially parallel to a gate line of the DRAM device in FIG. 8.

Hereinafter, a method for manufacturing a DRAM device with reference to FIG. 8 and FIGS. 9A to 9G is illustrated in detail.

Referring to FIG. 9A, transistors 210 are formed on a semiconductor substrate 200 that is divided into a cell region and peripheral region. The transistors include a gate electrode and source/drain regions. The transistor positioned in the cell region is indicated as a cell transistor 210a, and the transistor positioned in the peripheral region is indicated as a peripheral transistor 210b. A first insulating interlayer 212 is formed between the transistors. A pad electrode 214 is formed through the first insulating interlayer 212 so that the pad electrode 214 is electrically connected to the source/drain regions.

Particularly, a field oxide layer (not shown) is formed on the substrate 200 through an isolation process to divide the substrate 200 into an active region 200b (see FIG. 8) and a field region 200a. The transistors 210 are formed on the active region 200b through a deposition process, an etching process, and an ion implanting process.

The first insulating interlayer 212 is formed on the substrate 200. The first insulating interlayer 212 is etched to form a first contact hole 213 exposing the source/drain regions of the cell transistor 210a. Alternatively, the etching process may be performed through a self-aligned process. A doped polysilicon layer is formed on the transistors 210 and the substrate 200. An upper surface of the doped polysilicon layer is polished, exposing the first insulating interlayer 212 and forming the pad electrode 214 that is electrically connected to the source/drain regions. Referring to FIG. 9B, a second insulating interlayer 215 is formed on the pad electrode 214 and the first insulating interlayer 212. The second insulating interlayer 215 is etched to form a second contact hole 216 exposing an upper surface of the pad electrode 214 that is connected to the source region, and a third contact hole 218 exposing the source region or the drain region in the peripheral region. The first insulating interlayer 212 is selectively etched using an etchant having a high etching selectivity relative to the second insulating interlayer 215 and the pad electrode 214. Accordingly, second and third contact holes 216 and 218 having different depths, respectively, are simultaneously formed.

Referring to FIG. 9C, a metal barrier layer 230 is formed on an upper face of the second insulating interlayer 215, and on side and bottom faces of the second and third contact holes 216 and 218. The metal barrier layer 230 may include a titanium layer, a titanium nitride layer, or a multi-layer thereof.

A preliminary tungsten layer 232 is formed on the metal barrier layer 230 through a CVD process. The second and third contact holes 216 and 218 are filled with the preliminary tungsten layer 232. As a result, a bit line contact 217 is formed in the second and third contact holes 216 and 218. The preliminary tungsten layer 232 may be formed using tungsten fluoride (WF₆), silane (SiH₄), and hydrogen (H₂) as a source.

The preliminary tungsten layer 232 has a thickness thicker than that of a bit line considering a removed thickness of the preliminary tungsten layer 232 during a subsequent surface treatment. The preliminary tungsten layer 232 may have a thickness adding that of the bit line to about 50 Å to about 500 Å.

Referring to FIG. 9D, the surface treatment is performed on the preliminary tungsten layer 232 to form a tungsten layer 234. The surface treatment is preferably performed by removing the upper face of the preliminary tungsten layer 232 by a minimum amount thereby improving the surface morphology of the preliminary tungsten layer 232. When the preliminary tungsten layer 232 is rapidly etched, too much of the preliminary tungsten layer 232 is removed. As a result, the preliminary tungsten layer 232 is formed thicker that is sufficient to compensate for the removed thick thickness. Furthermore, the surface treatment may be performed for a minimum time to simplify processes for fabricating a DRAM device. The surface treatment is performed at an etching rate of below about 800 Å/min.

In particular, the surface treatment is performed in a vacuum chamber. A gas including chlorine is introduced into the vacuum chamber. The surface treatment is performed at a power of about 200 watts to about 1,000 watts under pressure of below about 200 mTorr. Magnetic force of about 10 gauss to about 50 gauss is applied to the vacuum chamber. The preliminary tungsten layer 232 is removed by a thickness of about 50 Å to about 500 Å. Also, the chlorine gas is introduced into the vacuum chamber at a flow rate of about 30 sccm to about 150 sccm for about 5 seconds to about 60 seconds.

Since the preliminary tungsten layer 232 has a thickness thicker than that of the bit line 217, the tungsten layer 234 has a thickness substantially equal to that of the bit line and improved surface morphology may be achieved.

Alternatively, the preliminary tungsten layer 232 and the tungsten layer 234 may be formed through an in-situ process in a single chamber. Alternatively, the preliminary tungsten layer 232 and the tungsten layer 234 may be formed through an ex-situ process.

Referring to FIGS. 8 and 9E, a hard mask layer 236 including silicon nitride is formed on the tungsten layer 234.

Referring to FIG. 9F, the hard mask layer 236 is etched to form a hard mask pattern 242 having intervals of below about 100 nm. The tungsten layer 234 is etched using the hard mask pattern 242 as a mask to form the bit line 240 electrically connected to the bit line contact 217. Referring to FIG. 9G, nitride spacers 244 are formed on sidewalls of the bit line 240 and the hard mask pattern 242. A third insulating interlayer 250 including silicon oxide that has an excellent gap filling characteristics is formed on the bit lines 240 and the hard mask pattern 242. Capacitor contacts 252 electrically connected to the pad electrode 214 are formed through the third insulating interlayer 250. A capacitor (not shown) is formed on the capacitor contacts 252.

As an interval between the bit lines becomes smaller than about 100 nm, an interval between the bit line and the capacitor contact is also reduced. When the bit line has a poor surface morphology, the bit line and the capacitor contact may be interconnected. However, the tungsten layer produced by embodiments of the invention has an improved surface morphology. When the tungsten layer is patterned to form the bit line, the bit line and the capacitor contact are rarely interconnected.

According to embodiments of the invention, a metal layer having an improved surface morphology may be obtained. Therefore, shorts caused by a poor surface morphology of a metal layer occur less frequently and the semiconductor fabricating yield may be advanced. Embodiments of the invention may be practiced in many ways. What follows are exemplary, non-limiting descriptions of some embodiments of the invention.

In accordance with a method for forming a metal layer according to one aspect of the invention, a preliminary metal layer having a first thickness is formed on a substrate. A surface of the preliminary metal layer having uneven portions is etched to remove the uneven portions to form a metal layer with a smooth surface.

In accordance with a method for manufacturing a semiconductor device according to another aspect of the invention, a conductive pattern is formed on a substrate. An insulating interlayer is formed on the substrate and the conductive pattern. The insulating interlayer is etched to form a contact hole for exposing an upper surface of the conductive pattern. A preliminary metal layer having a first thickness is formed on the insulating interlayer to fill the contact hole. A surface of the preliminary metal layer having uneven portions is etched to remove the uneven portions and to form a metal layer having a second thickness. The metal layer is etched to form a metal layer pattern.

In accordance with a method for manufacturing a semiconductor device according to still another aspect of the invention, MOS transistors having source/drain regions are formed on a substrate having a cell region and a peripheral region. A first insulating layer is formed on the MOS transistors. Contact pads are formed through the first insulating layer to make contact with the source/drain regions disposed in the cell region. A second insulating layer is formed on the contact pads. The second insulating layer is etched to form a contact hole exposing a bit line contact region. A preliminary metal layer having a first thickness is formed on the second insulating layer to fill the contact hole. A surface of the preliminary metal layer having uneven portions is etched to remove the uneven portions and to form a metal layer having a second thickness. The metal layer is etched to form a bit line.

According to embodiments of the invention, the preliminary metal layer has improved surface morphology due to a surface treatment. Therefore, when the metal layer is patterned, shorts between the metal layer and a conductive contact caused from the surface morphology occur less frequently.

Having described the preferred embodiments for forming the dielectric layers, it is noted that modifications and variations can be made by persons skilled in the art in light of the above teachings. It is therefore to be understood that changes may be made to the particular embodiments disclosed that are nevertheless within the scope and the spirit of the invention as defined by the appended claims.

We claim:

1. A method for forming a metal layer of a semiconductor device comprising:
forming a preliminary metal layer having a first thickness on a substrate; and
etching a surface of the preliminary metal layer for removing uneven portions formed on the surface of the preliminary metal layer to form a metal layer having a second thickness.

2. The method of claim 1, wherein etching the surface of the preliminary metal layer is performed using a gas including chlorine.

3. The method of claim 2, wherein the gas is provided on the substrate for about 5 seconds to about 60 seconds.

4. The method of claim 2, wherein the gas is provided on the substrate at a flow rate of about 30 sccm to about 150 sccm.

5. The method of claim 1, wherein etching the surface of the preliminary metal layer is performed at a power of about 200 watts to about 1,000 watts under a pressure of below 200 mTorr.

6. The method of claim 1, wherein etching the surface of the preliminary metal layer is performed in a chamber, and wherein a magnetic force of about 10 gauss to about 50 gauss is applied to the chamber.

7. The method of claim 1, wherein the metal layer comprises a tungsten layer, a titanium nitride layer or a tantalum nitride layer.

8. The method of claim 1, wherein forming the preliminary metal layer and etching the preliminary metal layer are performed through an in-situ process.

9. The method of claim 1, wherein the surface of the preliminary metal layer is etched at an etching rate of below about 800 Å/min.

10. The method of claim 1, wherein the first thickness corresponds to a thickness adding the second thickness to about 30 Å to about 500 Å.

11. The method of claim 1, further comprising etching the metal layer to form metal patterns after etching the surface of the preliminary metal layer.

12. The method of claim 11, wherein an interval between the metal patterns is below about 100 nm.

13. A method for manufacturing a semiconductor device comprising:
forming a conductive pattern on a substrate;
forming an insulating interlayer on the conductive pattern;
etching the insulating interlayer to form a contact hole exposing an upper face of the conductive pattern;
forming a preliminary metal layer having a first thickness on the insulating interlayer to fill the contact hole;
etching a surface of the preliminary metal layer for removing uneven portions formed on the surface of the preliminary metal layer to form a metal layer having a second thickness; and
etching the metal layer to form a metal pattern.

14. The method of claim 13, wherein etching the surface of the preliminary metal layer is performed using a gas including chlorine.

15. The method of claim 13, wherein etching the surface of the preliminary metal layer is performed at a power of about 200 watts to about 1,000 watts under a pressure of below about 200 mTorr.

16. The method of claim 13, wherein etching the surface of the preliminary metal layer is performed in a chamber, and wherein a magnetic force of about 10 gauss to about 50 gauss is applied to the chamber.

17. The method of claim 13, wherein forming the preliminary metal layer and etching the preliminary metal layer are performed through an in-situ process.

18. The method of claim 13, wherein the surface of the preliminary metal layer is etched at an etching rate of below about 800 Å/min.

19. The method of claim 13, wherein the first thickness corresponds to a thickness adding the second thickness to about 30 Å to about 500 Å.

20. A method for manufacturing a semiconductor device comprising:
forming MOS transistors on a substrate divided into a cell region and peripheral region;
forming a first insulating layer on the MOS transistors;
forming contact pads through the first insulating layer, the contact pads being electrically contact with source/drain regions of the MOS transistors;
forming a second insulating layer on the contact pads;
etching the second insulating layer to form a contact hole exposing a bit line contact region;
forming a preliminary metal layer having a first thickness on the second insulating layer to fill the contact hole;
etching a surface of the preliminary metal layer for removing uneven portions formed on the surface of the preliminary metal layer to form a metal layer having a second thickness; and
etching the metal layer to form a bit line.

21. The method of claim 20, wherein etching the surface of the preliminary metal layer is performed using a gas including chlorine.

22. The method of claim 20, wherein forming the preliminary metal layer and etching the preliminary metal layer are performed through an in-situ process.

23. The method of claim 20, wherein the bit line contact region includes an upper face of the contact pad connected to the source region, and source region or drain region of the MOS transistor positioned in the peripheral region.
